(19) United States
(12) Patent Application Publication
(10) Pub. No.: US 2024/0418801 A1
(43) Pub. Date: Dec. 19, 2024

(54) MAGNETIC SENSOR DEVICE

(71) Applicant: TDK CORPORATION, Tokyo (JP)

(72) Inventor: Kazuma YAMAWAKI, Tokyo (JP)

(73) Assignee: TDK CORPORATION, Tokyo (JP)

(21) Appl. No.: 18/743,261

(22) Filed: Jun. 14, 2024

(30) Foreign Application Priority Data
Jun. 14, 2023 (JP) 2023-097982

(51) Int. Cl. G01R 33/00

(52) U.S. Cl. CPC G01R 33/0094; G01R 33/0005

(57) ABSTRACT

A magnetic sensor device includes a plurality of magnetic detection element arrays formed in a first layer, and a wiring layer that is formed in a second layer different from the first layer and electrically connected to the plurality of magnetic detection element arrays. The plurality of magnetic detection element arrays include a first magnetic detection element array and a second magnetic detection element array, the first magnetic detection element array and the second magnetic detection element array are each configured of the same number of magnetic detection elements, and in a plane-normal direction from the second layer to the first layer, the number of magnetic detection elements of the first magnetic detection element array overlapping an outline of the wiring layer is substantially the same as the number of magnetic detection elements of the second magnetic detection element array overlapping the outline of the wiring layer.

### CROSS-REFERENCES TO RELATED APPLICATIONS

This application claims the benefit of Japanese Priority Patent Application No. 2023-097982 filed on Jun. 14, 2023, the entire contents of which are incorporated herein by reference.

### BACKGROUND

The present disclosure relates to a magnetic sensor device.

A magnetic sensor device includes a magnetic detection element made of a magnetic material. When an external force is applied to a magnetic material, a response to a magnetic field thereof fluctuates due to an inverse magnetostriction effect. In particular, while a tunnel magnetoresistance effect element has excellent output characteristics with a large MR ratio, output characteristics thereof tend to fluctuate due to an external force (for example, see JP-A-2005-277034).

The present disclosure has been made in view of these circumstances, and an object thereof is to provide a magnetic sensor device that has a high degree of freedom in designing a wiring layer and has stable output characteristics.

### SUMMARY

A magnetic sensor device according to one aspect of the present disclosure includes a plurality of magnetic detection element arrays formed in a first layer, and a wiring layer that is formed in a second layer different from the first layer and electrically connected to the plurality of magnetic detection element arrays. The plurality of magnetic detection element arrays include a first magnetic detection element array and a second magnetic detection element array, the first magnetic detection element array and the second magnetic detection element array are each configured of the same number of magnetic detection elements, and in a plane-normal direction from the second layer to the first layer, the number of magnetic detection elements of the first magnetic detection element array overlapping an outline of the wiring layer is substantially the same as the number of magnetic detection elements of the second magnetic detection element array overlapping the outline of the wiring layer.

According to the present disclosure, it is possible to provide a magnetic sensor device that has a high degree of freedom in designing a wiring layer and has stable output characteristics.

### BRIEF DESCRIPTION OF DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device according to one example embodiment;

FIG. 2 is a cross-sectional view schematically showing an example of an internal structure of the magnetic sensor device shown in FIG. 1;

FIGS. 3A to 3G are perspective views illustrating a manufacturing process of the magnetic sensor device shown in FIG. 1;

FIGS. 4A and 4B are diagrams showing an example of the magnetic sensor device configured as an angle sensor;

FIG. 5 is a plan view showing an example of the magnetic sensor device configured as a magnetic compass;

FIG. 6 is a diagram showing an example of the magnetic sensor device used as part of a current sensor;

FIG. 7 is a diagram showing a circuit configuration of the current sensor shown in FIG. 6;

FIG. 8 is a perspective view showing an example of the magnetic sensor device used as part of an autofocus mechanism and an optical image stabilization mechanism of a camera module;

FIG. 9 is a cross-sectional view showing an internal structure of the camera module shown in FIG. 8;

FIG. 10 is a plan view of a simulation model viewed in a plane-normal direction;

FIG. 11 is a cross-sectional view of the simulation model along an XY plane orthogonal to the plane-normal direction;

FIG. 12 is a diagram showing simulated angular errors at each position shown in FIGS. 10 and 11;

FIG. 13 is a plan view showing a first example configured such that the influence of the thermal stress is balanced between the magnetic detection element arrays;

FIG. 14 is a plan view showing a second example configured such that the influence of the thermal stress is balanced between the magnetic detection element arrays;

FIG. 15 is a plan view showing a third example configured so that the influence of the thermal stress is balanced between the magnetic detection element arrays;

FIG. 16 is a plan view showing a fourth example configured such that the influence of the thermal stress is balanced between the magnetic detection element arrays;

FIG. 17 is a plan view showing a fifth example configured such that the influence of the thermal stress is balanced between the magnetic detection element arrays; and

FIG. 18 is a plan view showing an example in which the influence of the thermal stress is not balanced between the magnetic detection element arrays, shown for comparison with FIGS. 13 to 17.

### DETAILED DESCRIPTION

Among magnetic sensor devices, there is one in which a magnetic detection element is electrically connected to the outside using a wiring layer that is not flexible, rather than a bonding wire that is flexible. In such a magnetic sensor device, there is a risk that a thermal stress in the wiring layer, which expands or contracts due to a change in temperature, may act on the magnetic detection element. JP-A-2005-277034 discloses a semiconductor device in which, in order to solve the problem that, when the semiconductor device is heated, a stress occurs due to thermal deformation of a wiring layer and the stress in the wiring layer reaches a sensor element, a wiring portion is disposed at a position at which it does not overlap the sensor element in a thickness direction of a semiconductor chip.

However, in the semiconductor device of JP-A-2005-277034, since the wiring portion must be detoured to the position at which it does not overlap the sensor element in the thickness direction of the semiconductor chip, a layout of the wiring portion is greatly restricted.

The present disclosure has been made in view of these circumstances, and an object thereof is to provide a magnetic sensor device that has a high degree of freedom in designing a wiring layer and has stable output characteristics.

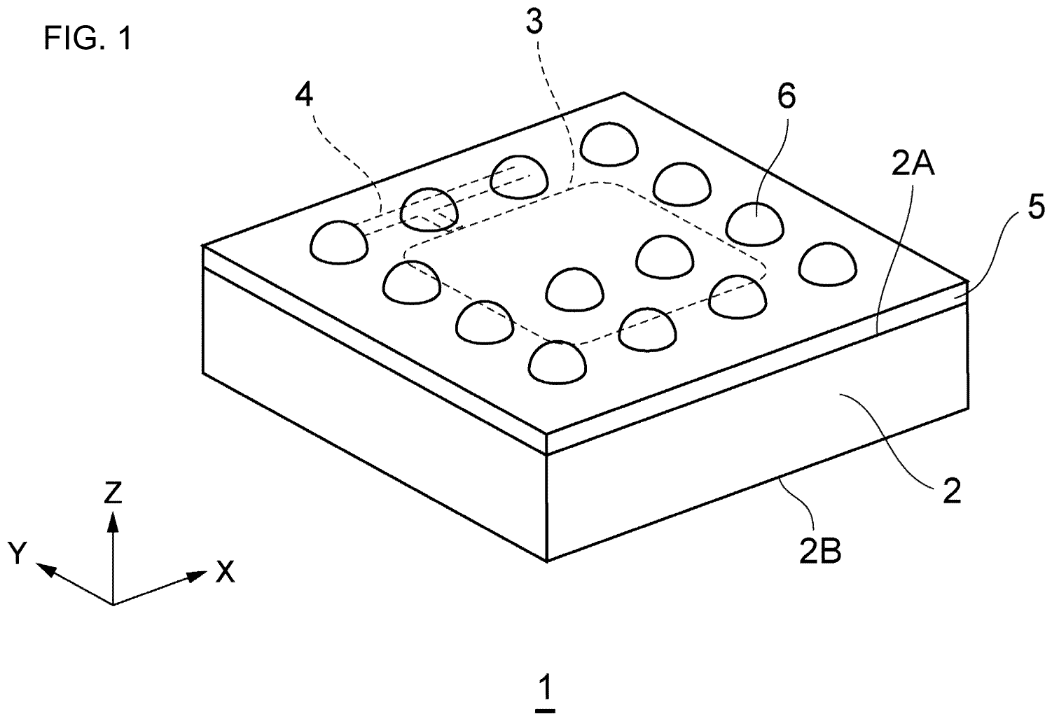

A preferred example embodiment will be described with reference to the accompanying drawings. In addition, in each figure, those with the same reference numerals have the same or similar configurations. FIG. 1 is a perspective view showing a magnetic sensor device 1 according to one example embodiment. As illustrated, the magnetic sensor device 1 may include a support substrate 2, a sensor chip 3, a wiring layer 4, a sealing resin 5, electrodes 6, and the like. One magnetic sensor device 1 may include a plurality of sensor chips 3.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology.

Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. As shown in FIG. 1, the support substrate 2 may be formed into a flat plate shape having a first surface 2A and a second surface 2B on a side opposite to the first surface 2A. In the following description, a thickness direction of the support substrate 2 will be referred to as a plane-normal direction Z or a vertical direction Z, a direction from the second surface 2B to the first surface 2A will be referred to as upward, and a direction from the first surface 2A to the second surface 2B will be referred to as downward. The first surface 2A may extend in parallel along an XY plane orthogonal to the plane-normal direction Z.

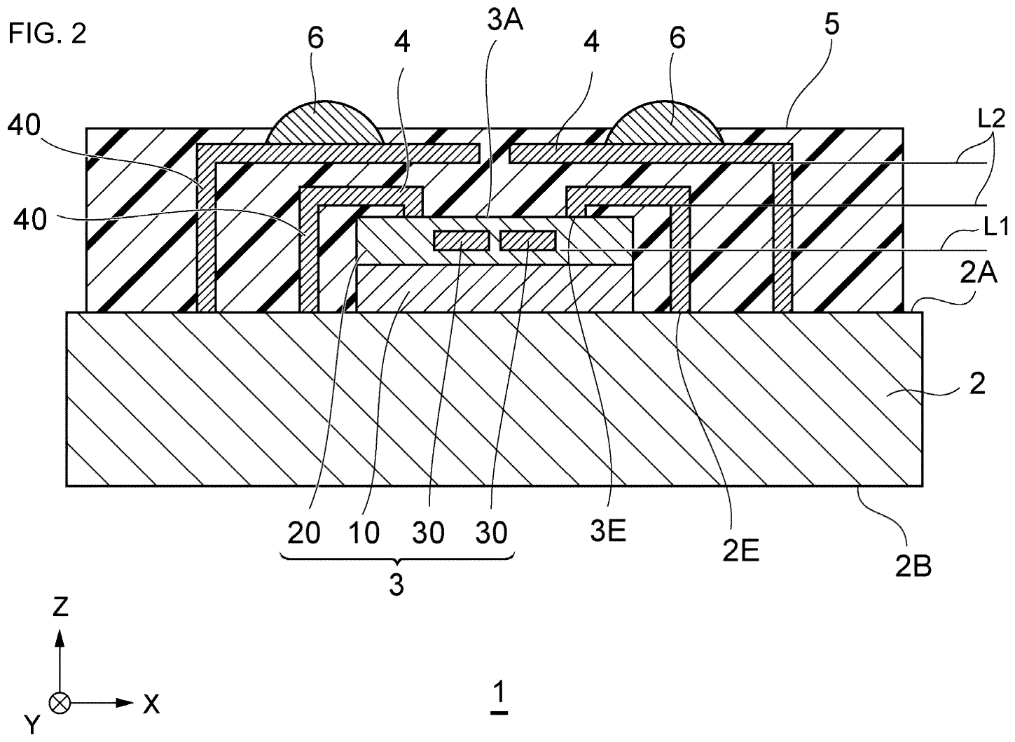

FIG. 2 is a cross-sectional view schematically showing an example of an internal structure of the magnetic sensor device 1 shown in FIG. 1. As illustrated, the support substrate 2 may be an application specific integrated circuit (ASIC). Electrodes 2E electrically connected to the wiring layer 4 are provided on the first surface 2A. The support substrate 2 is not limited to an ASIC and may be a silicon substrate or a sapphire substrate. It may be a relay substrate (an interposer) on which only wirings without integrated circuits are formed.

The sensor chip 3 may be fixed to the first surface 2A of the support substrate 2 with an adhesive or the like. As shown in FIG. 2, the sensor chip 3 may include a sensor substrate 10, a plurality of magnetic detection element arrays 30 provided on the sensor substrate 10, a protective film 20 surrounding each of the magnetic detection element arrays 30, and the like.

The sensor substrate 10 is, for example, a silicon substrate and is disposed between the first surface 2A of the support substrate 2 and the protective film 20. The configuration of the magnetic sensor device 1 is not limited to the illustrated example, and may be a monolithic structure in which the sensor substrate 10 is omitted, and the support substrate 2 and the magnetic detection element arrays 30 are configured as an integral structure by photolithography. The protective film 20 may be an inorganic film mainly composed of silica (silicon dioxide, SiO2), or may be a layered film of an inorganic film mainly composed of silica and an inorganic film mainly composed of alumina (aluminum oxide Al₂O₃).

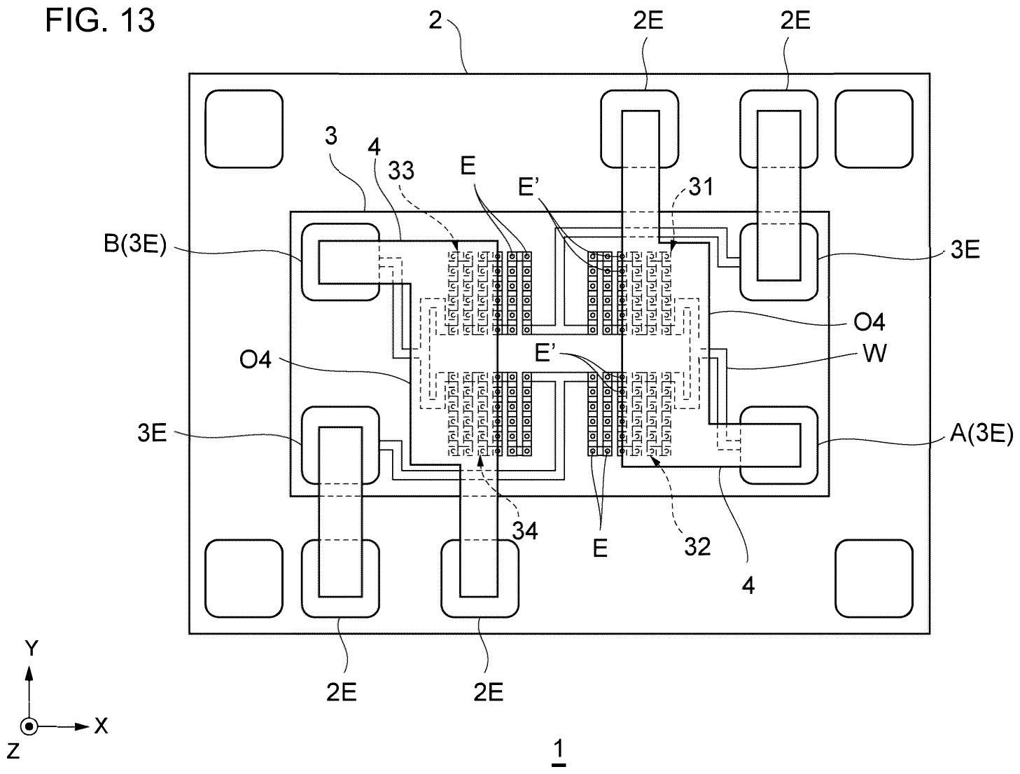

Each of the magnetic detection element arrays 30 may be configured of a plurality of magnetic detection elements E (shown in FIG. 13) connected in a daisy chain and arranged in a matrix. An example of the magnetic detection element E may be a tunnel magnetoresistance effect (TMR) element. The magnetic detection element E is not limited to a TMR element, and may be a giant magnetoresistance effect (GMR) element, an anisotropic magnetoresistance effect (AMR) element, a Hall effect element, or another type of magnetic detection element. A TMR element is particularly suitable for the magnetic detection element E because it has a small junction area compared to other types of MR elements, allowing the sensor chip 3 to be made smaller, and has a large MR ratio, allowing an output of the sensor chip 3 to be increased.

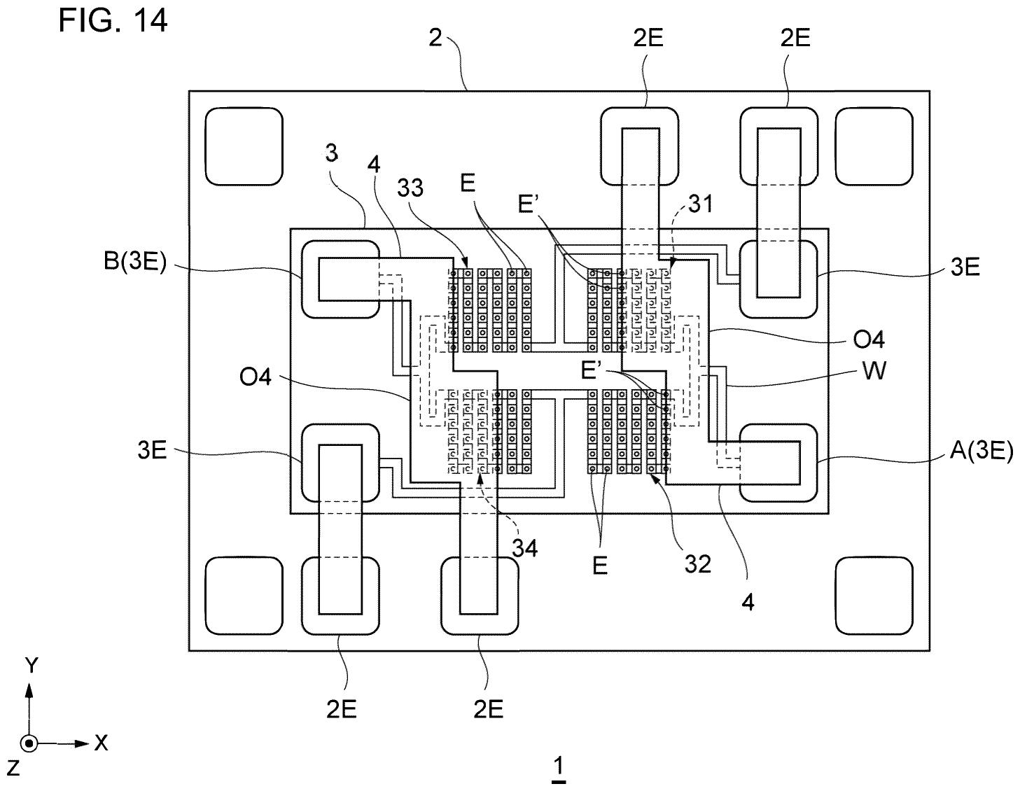

The magnetic detection element arrays 30 may be disposed on the first surface 2A side of the support substrate 2 and formed in a first layer L1 on the first surface 2A side of the support substrate 2. The wiring layer 4 may be disposed on the first surface 2A side of the support substrate 2 and formed in a second layer L2 different from the first layer L1. A dummy pattern 4D (shown in FIG. 14), which will be described later, may be formed in the second layer L2 similarly to the wiring layer 4.

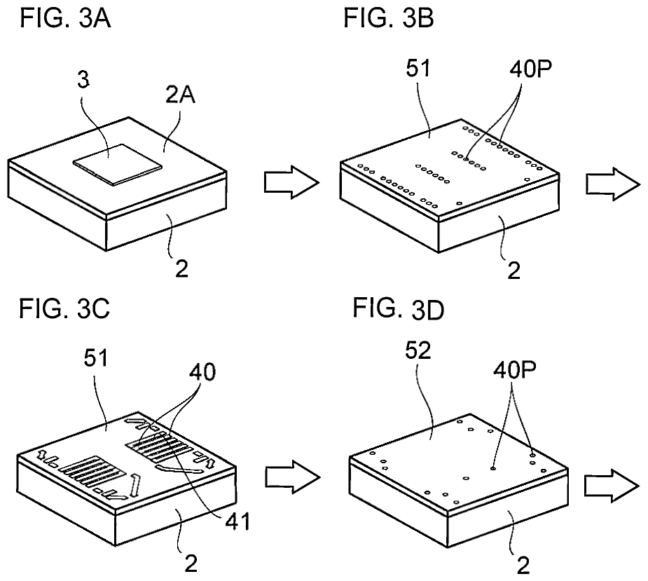

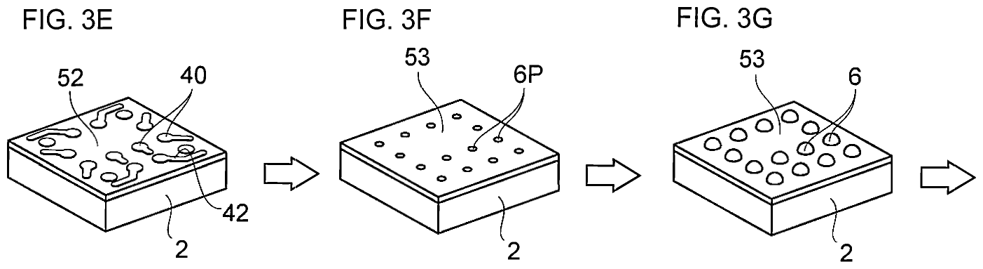

The second layer L2 is not particularly limited as long as it is a layer different from the first layer L1 and may be a plurality of layers. For example, the second layer L2 may be an upper surface of a first resin layer 51 (shown in FIGS. 3A to 3G), which will be described later, or an upper surface of a second resin layer 52 (shown in FIGS. 3A to 3G). In either case, the second layer L2 is located at a more distant position from the support substrate 2 than the first layer L1. A direction from the first layer L1 to the second layer L2 corresponds to the above-described plane-normal direction Z.

The wiring layer 4 may extend in parallel along the first surface 2A of the support substrate 2 and electrically connect the electrodes 2E of the support substrate 2 to the electrodes 3E provided on an upper surface 3A of the sensor chip 3 via a plurality of vias 40 extending in the plane-normal direction Z. The wiring layer 4 may be disposed to partially overlap the sensor substrate 10 in the plane-normal direction Z.

The sealing resin 5 may be disposed on the first surface 2A side of the support substrate 2 and may cover the sensor chip 3 and the wiring layer 4. The sealing resin 5 may be configured by layering a plurality of resin layers 51, 52, 53 (shown in FIGS. 3A to 3G) extending in parallel along the first surface 2A of the support substrate 2. The wiring layer 4 and the dummy pattern 4D (shown in FIG. 14) may be, for example, copper plating provided on upper surfaces of the resin layers 51 and 52. The electrodes 6 are, for example, solder balls or copper pillars, and may be electrically connected to the wiring layer 4 and exposed from the sealing resin 5.

FIGS. 3A to 3G are perspective views illustrating a manufacturing process of the magnetic sensor device 1 shown in FIG. 1. As shown in FIG. 3A, the sensor chip 3 may be fixed to the first surface 2A of the support substrate 2 with an adhesive or the like. As shown in FIG. 3B, the resin layer (first resin layer) 51 may be formed to cover the sensor chip 3 and the first surface 2A of the support substrate 2, or through holes 40P for the vias 40 (shown in FIG. 2) may open at positions of the electrodes 2E and 3E (shown in FIGS. 13 and 14).

As shown in FIG. 3C, a seed layer may be formed by sputtering or the like, and the vias 40 and the first wiring layer 41 may be formed by plating.

These processes may be subtractive methods or additive methods. As shown in FIG. 3D, the resin layer (second resin layer) 52 may be formed to cover the vias 40, the first wiring layer 41, and the resin layer 51, and the through holes 40P for the vias 40 may be open.

As shown in FIG. 3E, the vias 40 and the second wiring layer 42 may be formed by a process similar to that in FIG. 3C. As shown in FIG. 3F, the resin layer (third resin layer) 53 may be formed to cover the vias 40, the second wiring layer 42, and the resin layer 52, or through holes 6P for the electrodes 6 may open. As shown in FIG. 3G, the electrodes 6 may be formed by filling the through holes 6P with solder or the like. According to the procedure shown in FIGS. 3A to 3G, the magnetic sensor device 1 shown in FIG. 1 can be obtained by electrically connecting the separately prepared support substrate 2 to the sensor chip 3.

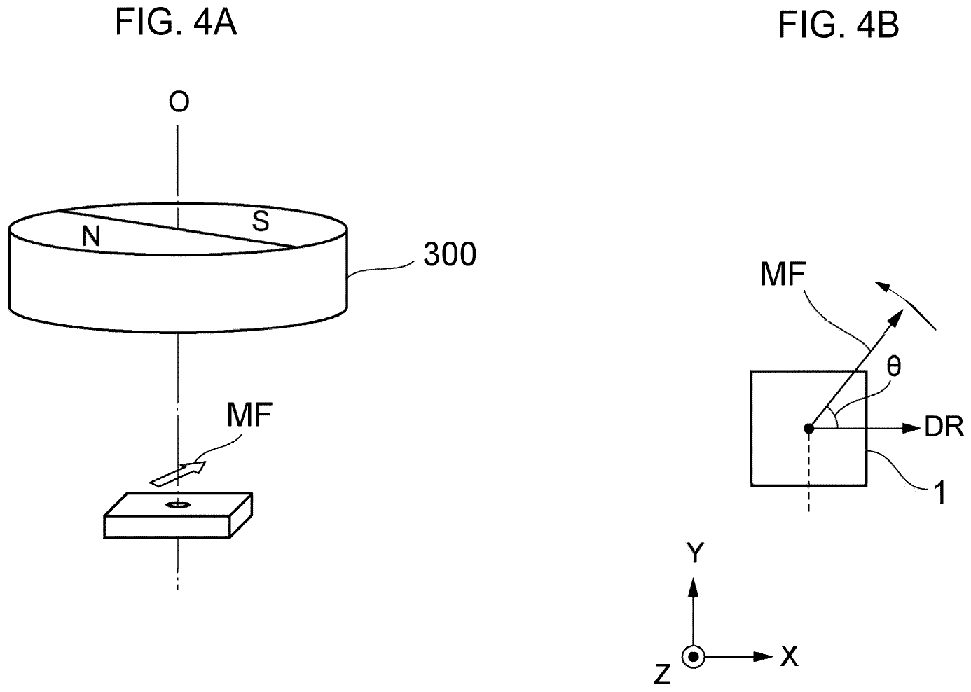

FIGS. 4A and 4B are diagrams showing an example of the magnetic sensor device 1 configured as an angle sensor that generates a detected value corresponding to an angle of a detection target. As illustrated, the magnetic sensor device 1 may be configured as an angle sensor that detects an angle of a rotatable magnet 300 with a central axis O of a cylinder as a rotation axis. In the illustrated example, the X direction, the Y direction, and the Z direction may be orthogonal to each other, and the central axis O may be parallel to the Z direction.

The magnetic sensor device 1 may detect a first component oriented in a direction parallel to the X direction of a magnetic field component MF, which is a magnetic field generated by the magnet 300 and applied to the magnetic sensor device 1, and generate a first detection signal representing an intensity of the first component, or may detect a second component oriented in a direction parallel to the Y direction of the magnetic field generated by the magnet 300 and generate a second detection signal representing an intensity of the second component. A processor (not shown) may calculate the angle θ that the magnetic field generated by the magnet 300 makes with respect to a reference direction DR by calculating an arctangent of a ratio of the first detection signal to the second detection signal.

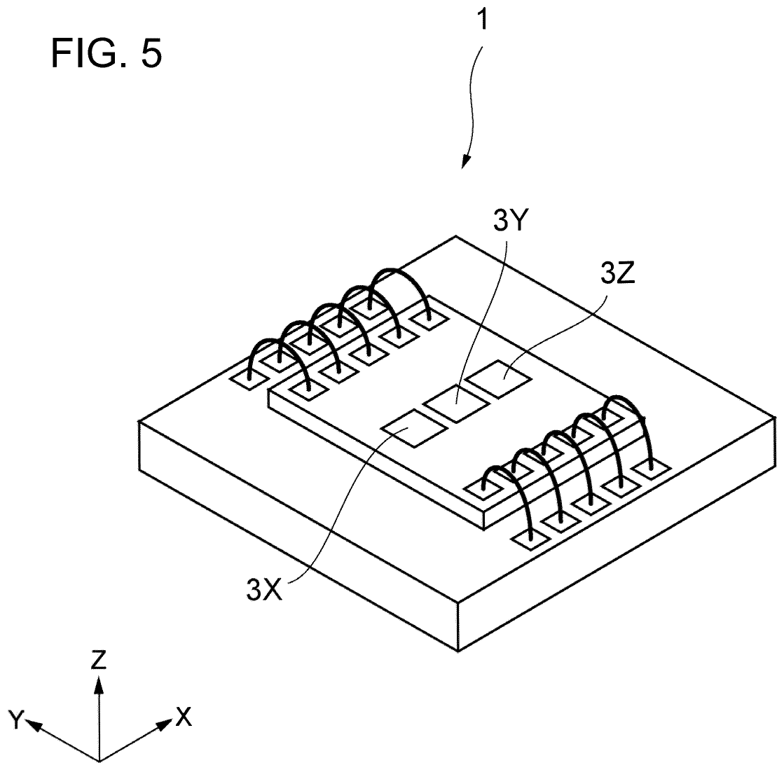

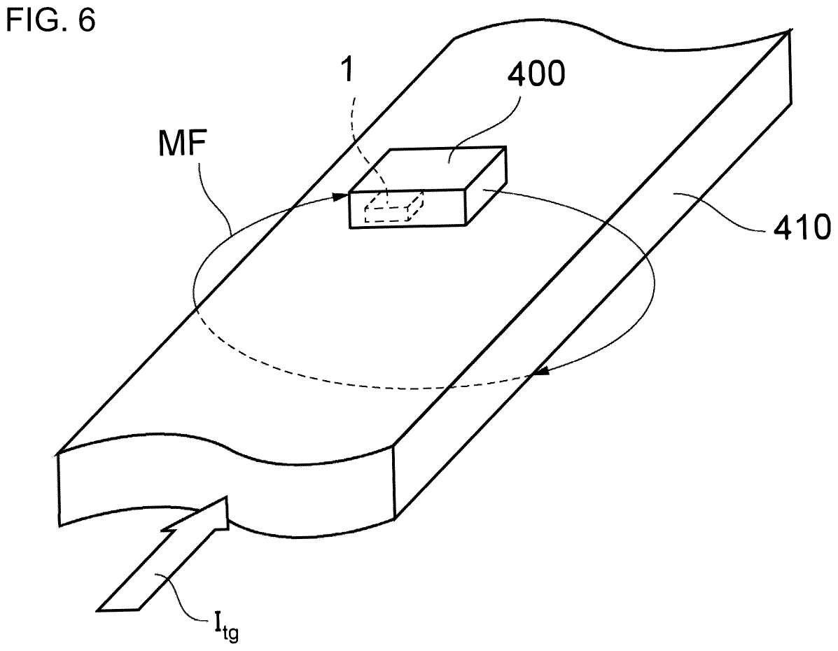

FIG. 5 is a diagram showing an example of the magnetic sensor device 1 configured as a magnetic compass that generates a detected value corresponding to an angle of geomagnetism. As shown in FIG. 5, the magnetic sensor device 1 may include three sensor chips 3 (first to third sensor chips 3X, 3Y, and 3Z), and may be configured such that the first to third sensor chips 3X, 3Y, and 3Z each detect components in three mutually orthogonal directions of an external magnetic field.

FIG. 6 is a diagram showing an example of the magnetic sensor device 1 used as part of a current sensor 400 that generates a detected value corresponding to a current value of a detection target. In the illustrated example, the current sensor 400 may be configured to detect a value of an electric current Itg flowing through a bus bar 410. A magnetic field MF is generated around the bus bar 410 by the electric current Itg. The current sensor 400 may be disposed near the bus bar 410 at a position to which the magnetic field MF is applied.

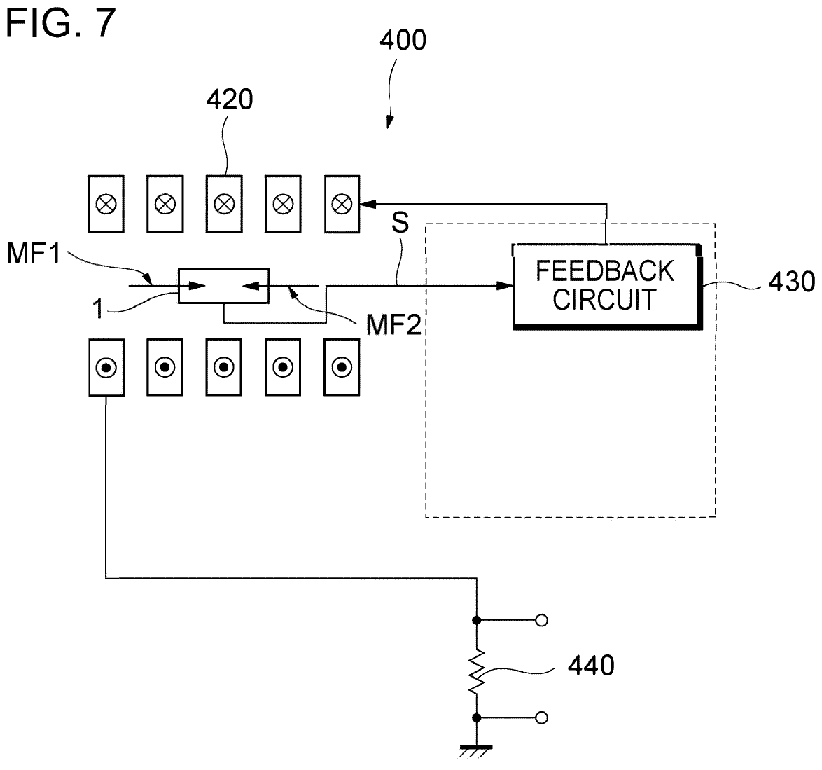

FIG. 7 is a diagram showing a circuit configuration of the current sensor 400 shown in FIG. 6. In the illustrated example, the current sensor 400 may be configured as a magnetically balanced current sensor. The current sensor 400 includes a coil 420 in addition to the magnetic sensor device 1. The coil 420 may be a coil for generating a second magnetic field MF2 that cancels out a first magnetic field MF1 of the magnetic field MF. The magnetic sensor device 1 may detect a residual magnetic field between the first magnetic field MF1 and the second magnetic field MF2 and generate a magnetic field detection value S in response to an intensity of the magnetic field.

The current sensor 400 may further include a feedback circuit 430, a current detector 440, and the like. The feedback circuit 430 may cause a feedback current for generating the second magnetic field MF2 to flow through the coil 420 on the basis of the magnetic field detection value S. The current detector 440 may detect a value of the feedback current flowing through the coil 420. The current detector 440 may be, for example, a resistor inserted in a current path of the feedback current. In that case, a potential difference across the resistor may correspond to a detected value of the feedback current. Since the detected value of the feedback current is proportional to a value of the electric current Itg of the bus bar 410, the value of the electric current Itg can be detected from the detected value of the feedback current.

The magnetic sensor device 1 of the present disclosure may be installed in an electronic device such as an information device and used as a magnetic compass that detects geomagnetism, may be used as part of an autofocus mechanism or an optical image stabilization mechanism of a camera module, may be used as an angle sensor that detects an angle formed by a magnetic field generated from a magnet with respect to a reference direction, or may be used as part of a current sensor that detects a value of an electric current flowing through a bus bar. According to these aspects, the magnetic sensor device 1 can be applied to various purposes.

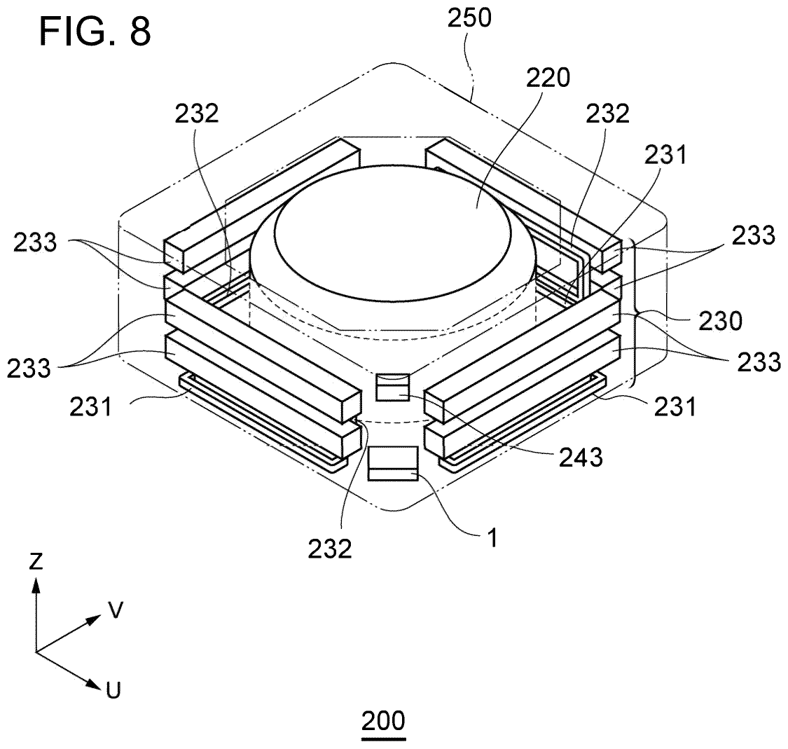

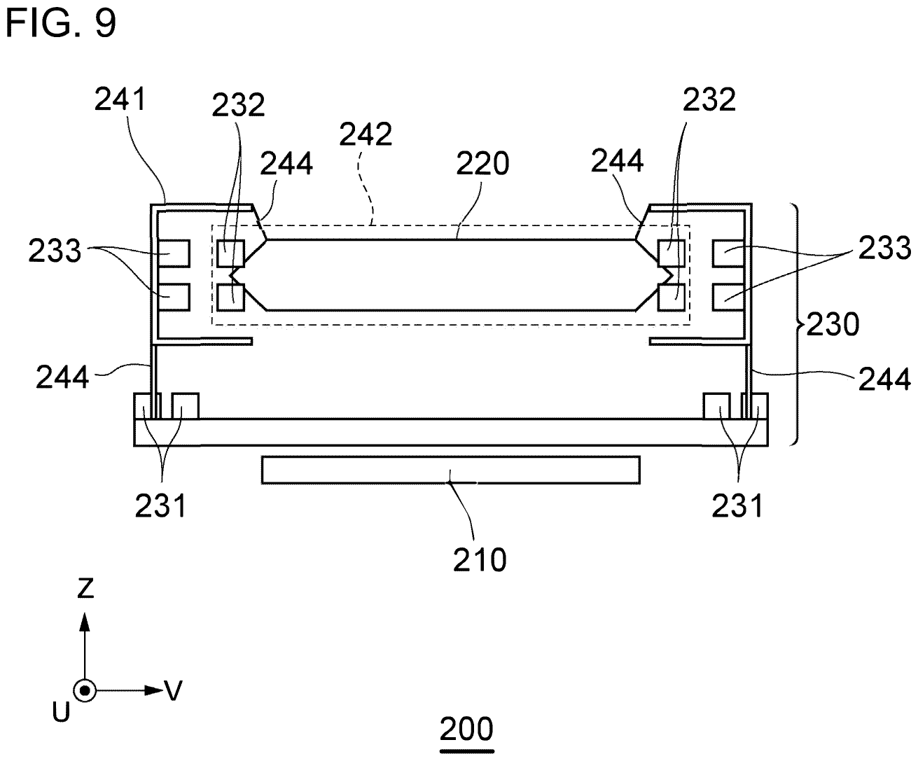

FIG. 8 is a perspective view showing an example of the magnetic sensor device 1 used as part of an autofocus mechanism and an optical image stabilization mechanism of a camera module 200. FIG. 9 is a cross-sectional view showing an internal structure of the camera module 200 shown in FIG. 8. The autofocus mechanism and the optical image stabilization mechanism of the camera module 200 may include a drive device 230 that moves a lens 220. The drive device 230 may be controlled on the basis of positional information of the lens 220 detected by a plurality of the magnetic sensor devices 1.

Specifically, the autofocus mechanism may detect a state in which a subject is in focus using an image sensor, autofocus sensor, or the like and move a lens in the Z direction relative to the image sensor. The optical image stabilization mechanism may detect camera shake using a gyro sensor or the like and move the lens in a U direction and/or a V direction with respect to the image sensor.

The camera module 200 shown in FIG. 8 may include an image sensor 210 such as CMOS, a lens 220 aligned with the image sensor 210, a first holding member 241 movable in the U direction and the V direction with respect to the image sensor 210, a second holding member 242 movable in the Z direction with respect to the first holding member 241, a plurality of elastically deformable wires 244 supporting the first holding member 241 and the second holding member 242, a drive device 230 that moves the first holding member 241 and the second holding member 242, and a housing 250 that accommodates them, and the like.

In addition to the drive device 230 and the plurality of magnetic sensor devices 1, the autofocus mechanism and the optical image stabilization mechanism of the camera module 200 may include a processor that controls the drive device 230, an autofocus sensor that detects a state in which a subject is in focus, a gyro sensor that detects camera shake, and the like. A processor, an autofocus sensor, a gyro sensor, and the like (not shown) may be disposed outside the housing.

The lens 220 may be fixed inside the second holding member 242 formed in a cylindrical shape. The second holding member 242 may be housed for each lens 220 in the first holding member 241 formed in a box shape. At least one second magnet 243 may be fixed to the second holding member 242 in order for at least one magnetic sensor device 1 to detect positional information of the second holding member 242.

The drive device 230 may include a plurality of first coils 231, a plurality of second coils 232, a plurality of first magnets 233, and the like. The plurality of first coils 231 may be fixed to the housing 250. The plurality of second coils 232 may be fixed to the second holding member 242. The plurality of first magnets 233 may be fixed to the first holding member 241. Each of the plurality of first coils 231 may face the corresponding first magnet 233. Each of the plurality of second coils 232 may face the corresponding first magnet 233. In the case of the autofocus mechanism, when an electric current flows through any second coil 232 in response to a command from the processor, due to the interaction between the magnetic field generated from the first magnet 233 and the magnetic field generated from the second coil 232, the second holding member 242 fixed to the second coil 232 may be moved in the Z direction. At least one magnetic sensor device 1 may generate a detection signal on the basis of a composite magnetic field in which a magnetic field generated from at least one second magnet 243 fixed to the second holding member 242 and a magnetic field generated from the first magnet 233 fixed to the first holding member 241 are combined together, and may transmit the detection signal to the processor. The processor may detect the positional information of the lens 220 in the Z direction from the detection signal and control the drive device 230 so that the subject is in focus.

In the case of the optical image stabilization mechanism, when an electric current flows through any first coil 231 in response to a command from the processor, due to the interaction between the magnetic field generated from the first magnet 233 and the magnetic field generated from the first coil 231, the first holding member 241 fixed to the first magnet 233 may be moved in the U direction and/or the V direction. Each of the plurality of magnetic sensor devices 1 may generate a detection signal on the basis of a position of the corresponding first magnet 233 and transmit it to the processor. The processor may detect the positional information of the lens 220 in the U direction and the V direction from the detection signal and control the drive device 230 to correct camera shake.

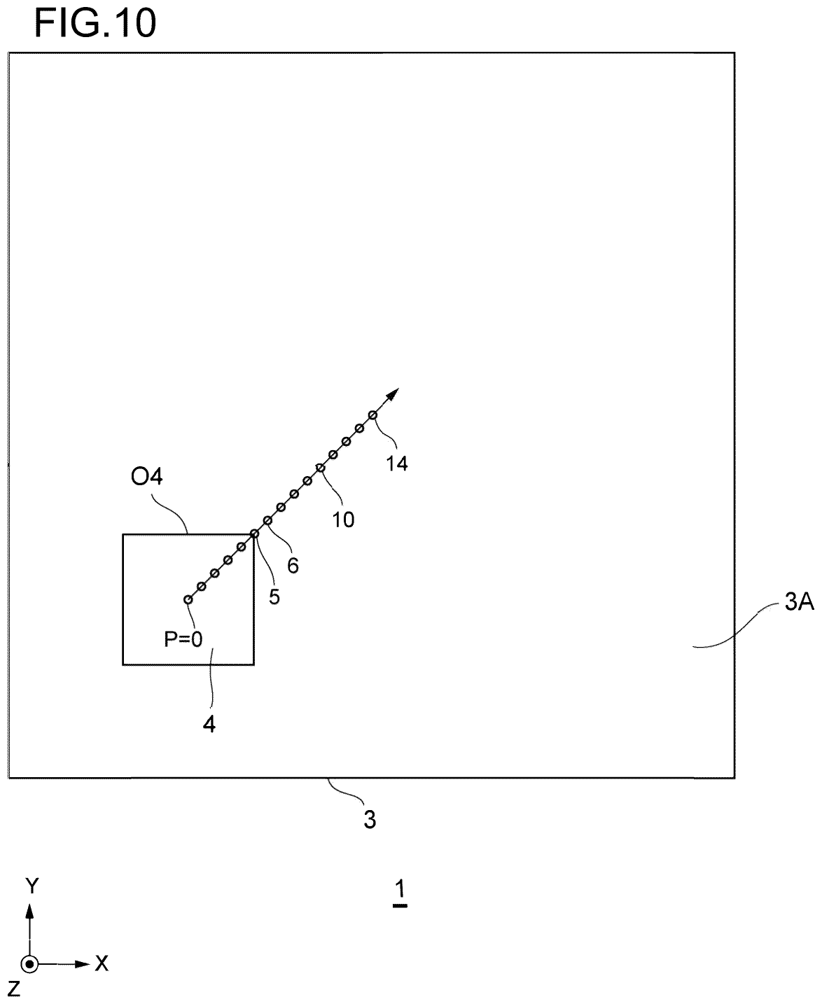

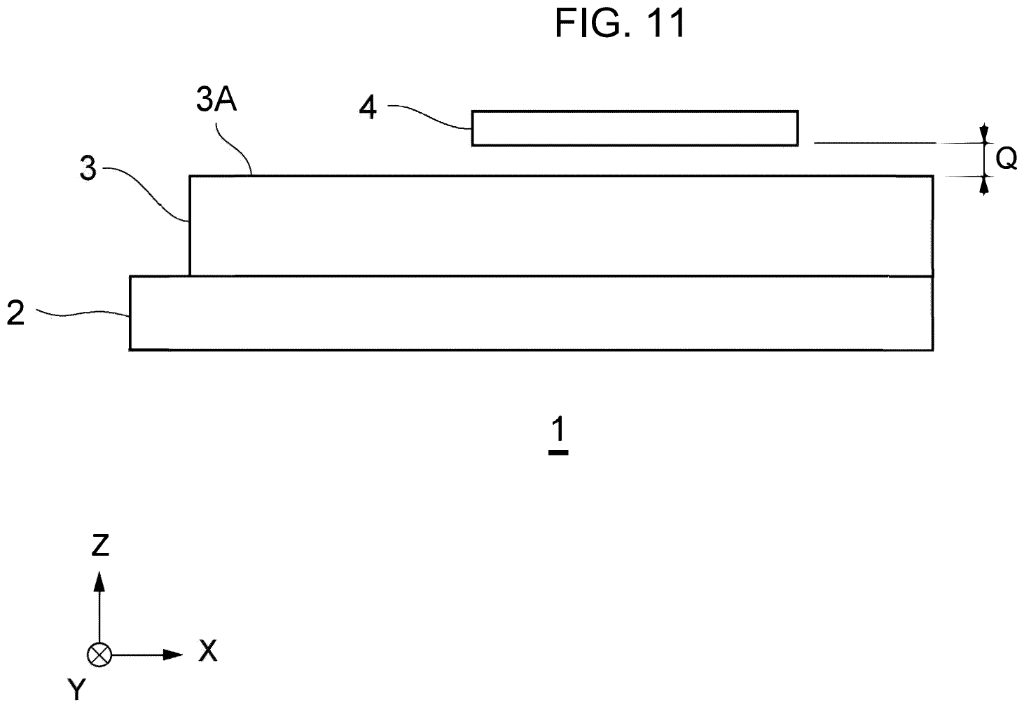

Next, the magnetic sensor device 1 of the present disclosure will be described in detail with reference to FIGS. 10 to 18. FIG. 10 is a plan view of a simulation model thereof when viewed in the plane-normal direction Z and shows positions P=0 to 14 plotted on the upper surface 3A of the sensor chip 3. As shown in FIG. 10, plotting is made with the position immediately below a center of the wiring layer 4 of 100 μm square in X axis and Y axis directions set as P=0, and the positions moved by 10 μm in the X axis direction and the Y axis direction set as P=1, 2, 3, . . . , and 14. For example, P=14 is located at positions 140 μm apart from P=0 in the X axis direction and the Y axis direction.

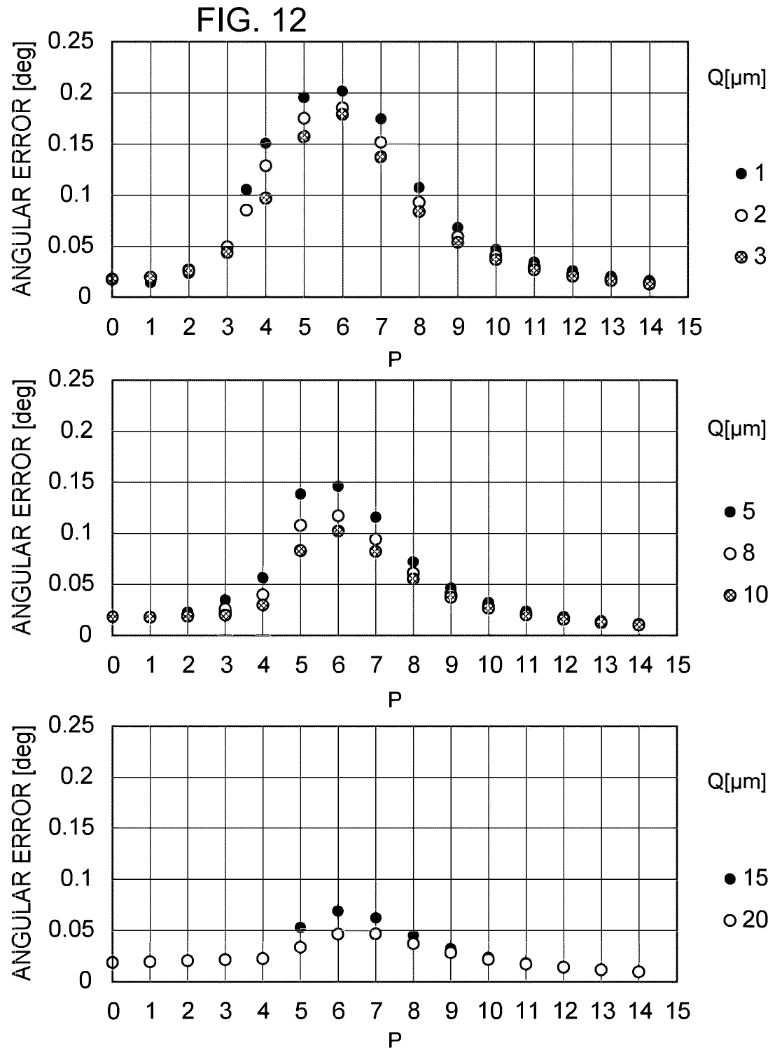

FIG. 11 is a cross-sectional view of the simulation model viewed along the XY plane orthogonal to the plane-normal direction Z. FIG. 12 is a diagram showing simulated angular errors at each distance Q shown in FIG. 11 at the position P shown in FIG. 10, and plots simulation results when a predetermined stress value is applied to the magnetic sensor device 1 while the position P shown in FIG. 10 is changed to 15 patterns from 0 to 14 as the horizontal axis and the distance Q from the upper surface 3A of the sensor chip 3 to the wiring layer 4 shown in FIG. 11 is changed to 8 patterns of 1 μm, 2 μm, 3 μm, 5 μm, 8 μm, 10 μm, 15 μm, and 20 μm as the vertical axis.

As shown in FIG. 12, there is a tendency for the angular error to become largest as the distance Q from the upper surface 3A of the sensor chip 3 to the wiring layer 4 becomes shorter. Regardless of the distance Q, the angular error is largest at the position P=5 overlapping an outline O4 of the wiring layer 4 in the plane-normal direction Z and the position P=6 in the vicinity thereof. When the magnetic detection element arrays 30 are located at these positions, they are likely to be influenced by the thermal stress from the wiring layer 4.

FIGS. 13 to 17 are plan views showing examples configured such that the influence of the thermal stress from the wiring layer 4 is balanced between a first magnetic detection element array 31 and a second magnetic detection element array 32. The magnetic sensor device 1 of the present disclosure includes a plurality of magnetic detection element arrays 30 formed on the first layer L1 (shown in FIG. 2). In the illustrated examples, the plurality of magnetic detection element arrays 30 include first to fourth magnetic detection element arrays 31, 32, 33, and 34.

In the examples shown in FIGS. 13 to 17, a bridge circuit is configured by two parallel circuits. The first magnetic detection element array 31 and the second magnetic detection element array 32 are connected in series to each other with an output port A interposed therebetween to form one parallel circuit of the bridge circuit, and the third magnetic detection element array 33 and the fourth magnetic detection element array 34 are connected in series to each other with an output port B interposed therebetween to form the other parallel circuit of the bridge circuit. The output ports A and B may be connected to the electrodes 2E.

As shown in FIGS. 13 to 17, one of features of the magnetic sensor device 1 of the present disclosure is a configuration in which, in order to balance the influence of the thermal stress received by the first magnetic detection element array 31 and the influence of the thermal stress received by the second magnetic detection element array 32, in a plan view seen in the plane-normal direction Z, the number of magnetic detection elements E′ overlapping the outline O4 of the wiring layer 4 or an outline OD of the dummy pattern 4D is made to be substantially the same between the first magnetic detection element array 31 and the second magnetic detection element array 32.

For example, in first to third examples shown in FIGS. 13 to 15, in the plane-normal direction Z, the outline O4 of the wiring layer 4 may overlap each of the first magnetic detection element array 31 and the second magnetic detection element array 32. The number of magnetic detection elements E′ overlapping the outline O4 of the wiring layer 4 may be the same, six for both in the first magnetic detection element array 31 and the second magnetic detection element array 32.

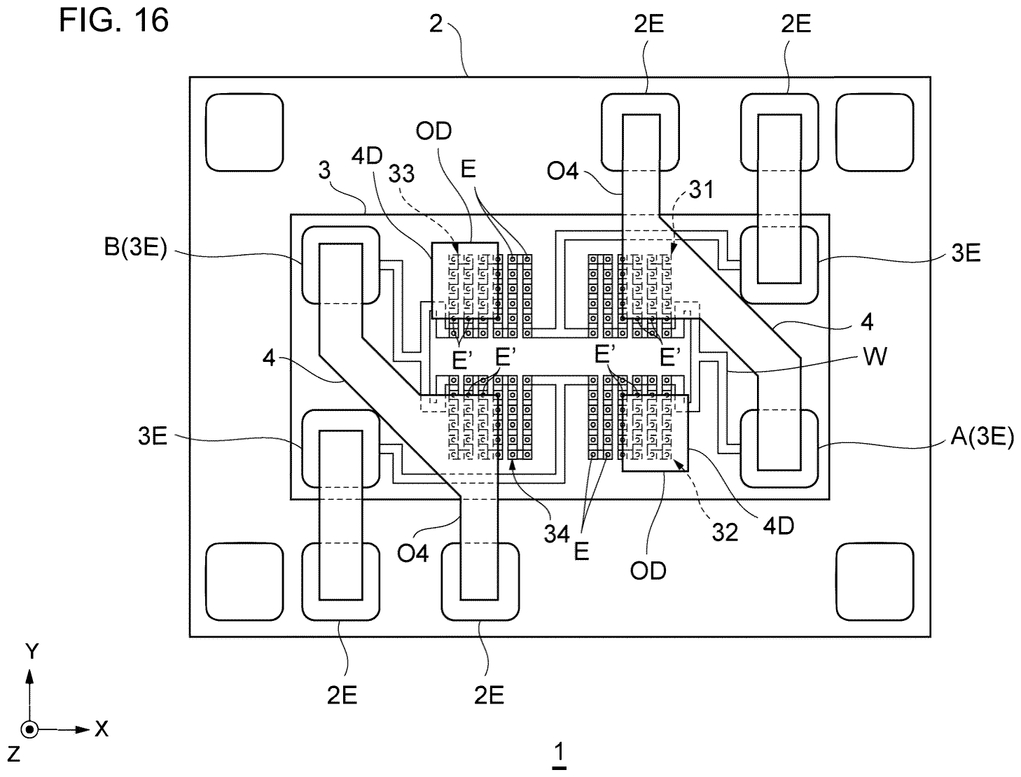

For example, in fourth and fifth examples shown in FIGS. 16 to 18, in the plane-normal direction Z, the outline O4 of the wiring layer 4 may overlap the first magnetic detection element array 31, and the dummy pattern 4D may overlap the second magnetic detection element array 32. The number of magnetic detection elements E′ in the first magnetic detection element array 31 overlapping the outline O4 of the wiring layer 4 and the number of magnetic detection elements E′ in the second magnetic detection element array 32 overlapping the outline OD of the dummy pattern 4D in the plane-normal direction Z may be the same, both eight.

As described above, each of the plurality of magnetic detection element arrays 30 may be configured of a plurality of magnetic detection elements E arranged in a matrix. In each of the magnetic detection element arrays 30, a plurality of magnetic detection elements E may be connected in series. In the illustrated example, in each of the magnetic detection element arrays 30, a plurality of magnetic detection elements E may be arranged at equal intervals. The magnetic detection element arrays 30 and the electrodes 3E may be electrically connected to each other by a wiring W formed in the first layer L1. The magnetic detection element arrays 30 and other magnetic detection element arrays 30 may be also electrically connected to each other by the wiring W.

In the magnetic sensor device 1 of the present disclosure, it is preferable when the influence of the thermal stress received by the first magnetic detection element array 31 and the influence of the thermal stress received by the second magnetic detection element array 32 are balanced. For that reason, when each of the first magnetic detection element array 31 and the second magnetic detection element array 32 includes a large number of magnetic detection elements E, the number of magnetic detection elements E′ overlapping the outline O4 of the wiring layer 4 or the outline OD of the dummy pattern 4D may not be strictly the same between the first magnetic detection element array 31 and the second magnetic detection element array 32, and may be slightly different. For example, when the magnetic detection element arrays 30 includes forty magnetic detection elements E, the influence of the thermal stress is reduced to 1/40 even when there is one magnetic detection element E′ overlapping the outline O4. For that reason, when each of the first magnetic detection element array 31 and the second magnetic detection element array 32 includes forty or more magnetic detection elements E, the number of magnetic detection elements E′ overlapping the outlines O4 and OD may be different by about one.

As described above, the dummy pattern 4D is formed in the second layer L2 similarly to the wiring layer 4. However, unlike the wiring layer 4, the dummy pattern 4D is not electrically connected to the plurality of magnetic detection element arrays 30. Further, the dummy pattern 4D is not electrically connected to the wiring layer 4 either.

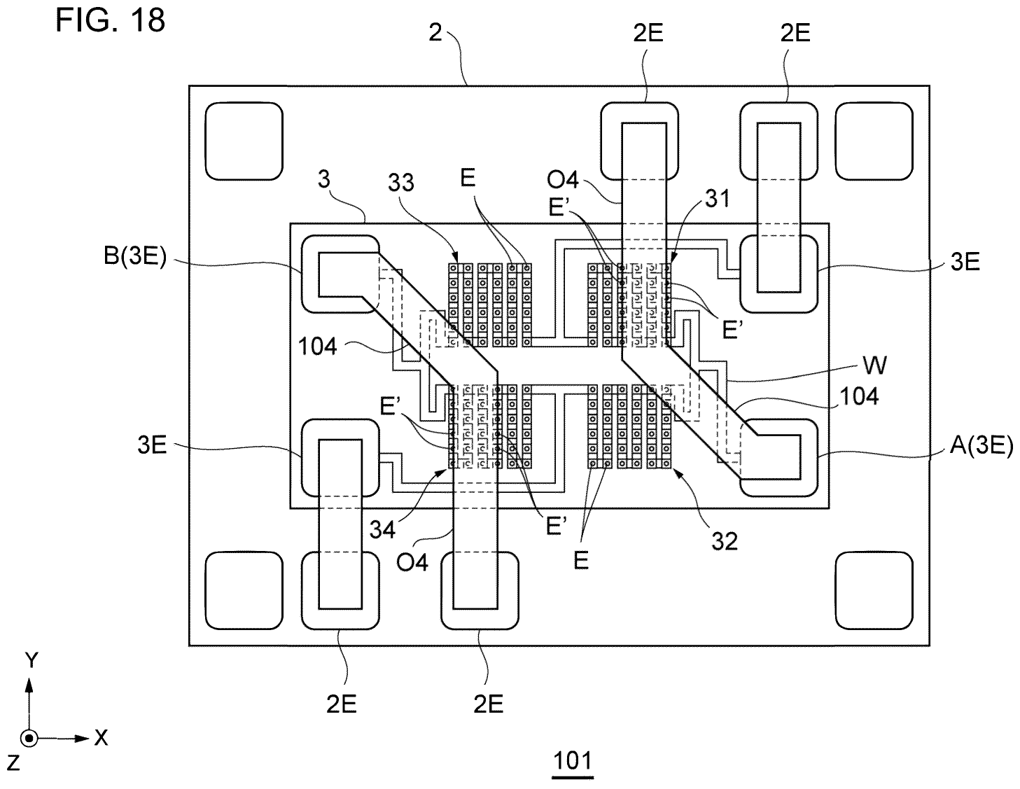

FIG. 18 is a plan view showing an example of the magnetic sensor device 101 in which the influence of the thermal stress of the wiring layer 4 is not balanced between the first magnetic detection element array 31 and the second magnetic detection element array 32, shown for comparison with FIGS. 13 to 17. In a magnetic sensor device 101 of a comparative example shown in FIG. 18, in the plane-normal direction Z, the number of magnetic detection elements E′ overlapping the outline O4 of the wiring layer 104 is not substantially the same between the first magnetic detection element array 31 and the second magnetic detection element array 32.

The number of magnetic detection elements E′ of the first magnetic detection element array 31 overlapping the outline O4 of the wiring layer 104 is twelve, the number of magnetic detection elements E′ of the second magnetic detection element array 32 overlapping the outline O4 of the wiring layer 104 is two, and there is a difference of ten. As described with reference to FIG. 12, in the plane-normal direction Z, the influence of the thermal stress of the rewiring 4 is likely to be received at the position overlapping the outline O4 of the wiring layer 4 (wiring layer 104).

In the magnetic sensor device 101 of the comparative example, since there is a large difference in the number of magnetic detection elements E′ that is likely to be influenced, there is a risk that the influence of the thermal stress received by the first magnetic detection element array 31 and the influence of the thermal stress received by the second magnetic detection element array 32 may not be balanced and output characteristics of the magnetic detection element arrays 30 may deteriorate.

On the other hand, in the examples of the present disclosure shown in FIGS. 13 to 17, in the plane-normal direction Z, the number of magnetic detection elements E′ overlapping the outline O4 of the wiring layer 4 or the outline OD of the dummy pattern 4D is substantially the same between the first magnetic detection element array 31 and the second magnetic detection element array 32, and thus the influence of the thermal stress received by the first magnetic detection element array 31 and the influence of the thermal stress received by the second magnetic detection element array 32 are balanced. Since a resistance ratio or the like is less likely to change between the first magnetic detection element array 31 and the second magnetic detection element array 32, the output characteristics of the magnetic detection element arrays 30 of the magnetic sensor device 1 are stabilized. For example, when the magnetic sensor device 1 may be configured as an angle sensor, angular errors can be reduced as shown in FIG. 12.

As described above, the first magnetic detection element array 31 and the second magnetic detection element array 32 may form one parallel circuit of the bridge circuit. When the resistance ratio or the like between the first magnetic detection element array 31 and the second magnetic detection element array 32 is less likely to change, equilibrium conditions of the bridge circuit are less likely to change. For that reason, the output characteristics of the magnetic sensor device 1 can be stabilized.

The first magnetic detection element array 31 and the second magnetic detection element array 32 may be configured of the same number of magnetic detection elements E, and may have the same area (this means that their areas may be equal; the same applies hereinafter). In the example of the present disclosure, in the plane-normal direction Z, an area of the region overlapping the wiring layer 4 or the dummy pattern 4D may be equal between regions of the first magnetic detection element array 31 and the second magnetic detection element array, or may be unequal (this means that their areas are unequal; the same applies hereinafter).

For example, in the first example shown in FIG. 13, an area of the region of the first magnetic detection element array 31 overlapping the wiring layer 4 may be 58% of the entire area of the first magnetic detection element array 31, and an area of the region of the second magnetic detection element array 32 overlapping the wiring layer 4 may be 58% of the entire area of the second magnetic detection element array 32. In the plane-normal direction Z, the area of the region overlapping the wiring layer 4 may be an equal area between the regions of the first magnetic detection element array 31 and the second magnetic detection element array. Further, a shape of the region of the equal area may have symmetry. In the illustrated example, the shape of the region of the equal area may be point symmetric. Although not illustrated, the shape of the region of the equal area may be axisymmetric.

On the other hand, in the second example shown in FIG. 14, the area of the region of the first magnetic detection element array 31 overlapping the wiring layer 4 may be 58% of the entire area of the first magnetic detection element array 31, and the area of the region of the second magnetic detection element array 32 overlapping the wiring layer 4 may be 4.5% of the entire area of the second magnetic detection element array 32. In the plane-normal direction Z, the area of the region overlapping the wiring layer 4 may be an unequal area between the regions of the first magnetic detection element array 31 and of the second magnetic detection element array. However, as described above, the number of magnetic detection elements E′ overlapping the outline O4 of the wiring layer 4 may be the same, six for both in the first magnetic detection element array 31 and the second magnetic detection element array 32.

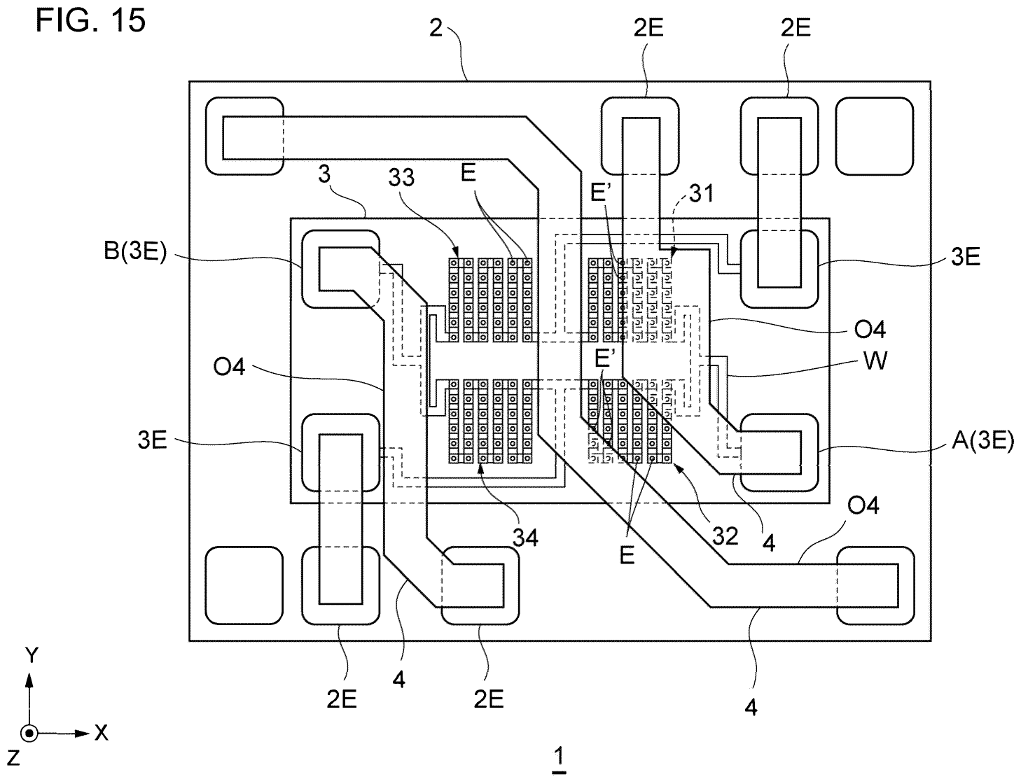

Similarly to the second example, in the third example shown in FIG. 15, the area of the region of the first magnetic detection element array 31 overlapping the wiring layer 4 may be 58% of the entire area of the first magnetic detection element array 31, and the area of the region of the second magnetic detection element array 32 overlapping the wiring layer 4 may be 21% of the entire area of the second magnetic detection element array 32, and they are unequal areas. However, as described above, the number of magnetic detection elements E′ overlapping the outline O4 of the wiring layer 4 may be the same, six for both in the first magnetic detection element array 31 and the second magnetic detection element array 32. In the third example, unlike the first and second examples, the region of the second magnetic detection element array 32 overlapping the wiring layer 4 may be divided into a plurality of regions.

Also, for example, in the fourth example shown in FIG. 16, the area of the region of the first magnetic detection element array 31 overlapping the wiring layer 4 may be 46% of the entire area of the first magnetic detection element array 31, and the area of the region of the second magnetic detection element array 32 overlapping the dummy pattern 4D may be 46% of the entire area of the second magnetic detection element array 32. In the plane-normal direction Z, the area of the region overlapping the wiring layer 4 or the dummy pattern 4D may be an equal area between the regions of the first magnetic detection element array 31 and the second magnetic detection element array. Similarly to the first example described above, the shape of the region of the equal area may have symmetry.

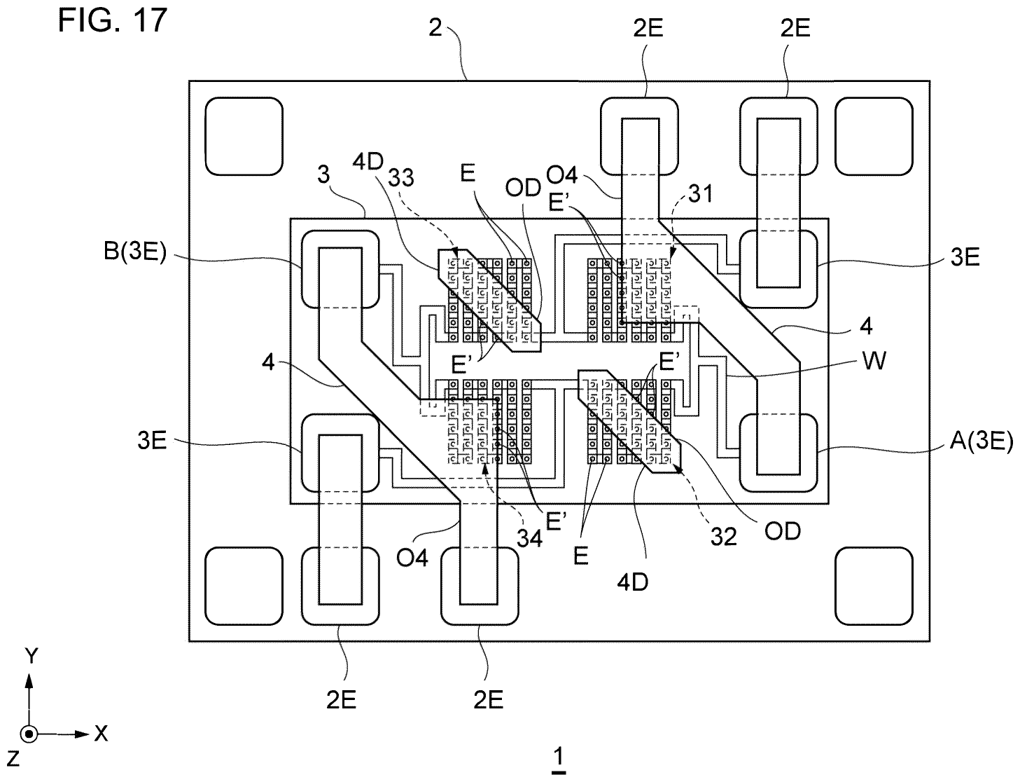

On the other hand, in the fifth example shown in FIG. 17, the area of the region of the first magnetic detection element array 31 overlapping the wiring layer 4 may be 46% of the entire area of the first magnetic detection element array 31, and the area of the region of the second magnetic detection element array 32 overlapping the dummy pattern 4D may be 60% of the entire area of the second magnetic detection element array 32. In the plane-normal direction Z, the area of the region overlapping the wiring layer 4 or the dummy pattern 4D may be an unequal area between the regions of the first magnetic detection element array 31 and the second magnetic detection element array. However, as described above, the number of magnetic detection elements E′ overlapping the outline O4 of the wiring layer 4 or the outline OD of the dummy pattern 4D may be the same, both eight in the first magnetic detection element array 31 and the second magnetic detection element array 32.

The example embodiments described above are intended to facilitate understanding of the present disclosure, and are not intended to be interpreted as limiting the present disclosure. Each of the elements included in the example embodiments, as well as their arrangements, materials, conditions, shapes, sizes, and the like are not limited to those illustrated, and can be changed as appropriate. Further, it is possible to partially replace or combine the structures shown in different example embodiments.

What is claimed is:

1. A magnetic sensor device comprising:
a plurality of magnetic detection element arrays formed in a first layer; and
a wiring layer that is formed in a second layer different from the first layer and electrically connected to the plurality of magnetic detection element arrays, wherein
the plurality of magnetic detection element arrays include a first magnetic detection element array and a second magnetic detection element array, and the first magnetic detection element array and the second magnetic detection element array are each configured of the same number of magnetic detection elements, and
in a plane-normal direction from the second layer to the first layer, the number of magnetic detection elements of the first magnetic detection element array overlapping an outline of the wiring layer is substantially the same as the number of magnetic detection elements of the second magnetic detection element array overlapping the outline of the wiring layer.

2. The magnetic sensor device according to claim 1,
wherein the first magnetic detection element array and the second magnetic detection element array are connected in series to each other, with an output port being interposed therebetween to form part of a bridge circuit.

3. The magnetic sensor device according to claim 1,
wherein, in the plane-normal direction, a region of the first magnetic detection element array overlapping the wiring layer and a region of the second magnetic detection element array overlapping the wiring layer have unequal areas.

4. An angle sensor comprising the magnetic sensor device according to claim 1.

5. A magnetic compass comprising the magnetic sensor device according to claim 1.

6. A current sensor comprising the magnetic sensor device according to claim 1.

7. A camera module comprising an autofocus mechanism and/or an optical image stabilization mechanism including the magnetic sensor device according to claim 1.

8. A magnetic sensor device comprising:
a plurality of magnetic detection element arrays formed in a first layer;
a wiring layer that is formed in a second layer different from the first layer and electrically connected to the plurality of magnetic detection element arrays; and
a dummy pattern that is formed in the second layer and not electrically connected to the plurality of magnetic detection element arrays, wherein
the plurality of magnetic detection element arrays include a first magnetic detection element array and a second magnetic detection element array, and the first magnetic detection element array and the second magnetic detection element array are each configured of the same number of magnetic detection elements, and
in a plane-normal direction from the second layer to the first layer, the number of magnetic detection elements of the first magnetic detection element array overlapping an outline of the wiring layer is substantially the same as the number of magnetic detection elements of the second magnetic detection element array overlapping an outline of the dummy pattern.

9. The magnetic sensor device according to claim 8,
wherein the first magnetic detection element array and the second magnetic detection element array are connected in series to each other, with an output port being interposed therebetween to form part of a bridge circuit.

10. The magnetic sensor device according to claim 8,
wherein, in the plane-normal direction, a region of the first magnetic detection element array overlapping the wiring layer and a region of the second magnetic detection element array overlapping the wiring layer have an equal area.

11. The magnetic sensor device according to claim 8,
wherein, in the plane-normal direction, a region of the first magnetic detection element array overlapping the wiring layer and a region of the second magnetic detection element array overlapping the dummy pattern have an equal area.

12. The magnetic sensor device according to claim 8,
wherein, in the plane-normal direction, a region of the first magnetic detection element array overlapping the wiring layer and a region of the second magnetic detection element array overlapping the dummy pattern have unequal areas.

13. An angle sensor comprising the magnetic sensor device according to claim 8.

14. A magnetic compass comprising the magnetic sensor device according to claim 8.

15. A current sensor comprising the magnetic sensor device according to claim 8.

16. A camera module comprising an autofocus mechanism and/or an optical image stabilization mechanism including the magnetic sensor device according to claim 8.
